(19) United States
(12) Patent Application Publication
(10) Pub. No.: US 2024/0208801 A1
(43) Pub. Date: Jun. 27, 2024

(54) MICRO-ELECTRO-MECHANICAL SYSTEM (MEMS) VIBRATION SENSOR AND FABRICATING METHOD THEREOF

(71) Applicant: UPBEAT TECHNOLOGY Co., Ltd, New Taipei City (TW)

(72) Inventors: Hsi-Wen TUNG, New Taipei City (TW); Hsien-Lung HO, New Taipei City (TW)

(21) Appl. No.: 17/747,879

(22) Filed: May 18, 2022

Related U.S. Application Data
(60) Provisional application No. 63/189,752, filed on May 18, 2021.

(51) Int. Cl. B81B 3/00; B81C 1/00

(52) U.S. Cl. CPC B81B 3/0021; B81C 1/00182; B81B 2201/0257; B81B 2201/0285; B81B 2203/0315; B81B 2203/0353; B81C 2201/013; B81C 2201/0159; B81C 2201/053

(57) ABSTRACT

A MEM vibration sensor includes a substrate and a sensing-device. The substrate includes a first supporting-portion and a cavity. The sensing-device includes a first sensing-unit, a second sensing-unit, a first metal pad and a second metal pad. The first sensing-unit includes a second supporting-portion and a vibrating-portion. The second supporting-portion is located on the first supporting-portion and is connected to the first supporting-portion via a first dielectric material. The vibrating-portion is located on the cavity, and is connected with the second supporting-portion through an elastic connecting-portion. The second sensing-unit is located on the first sensing-unit and includes a sensing-portion and a third supporting-portion. The sensing-portion is located on the vibrating-portion and has a gap with the vibrating-portion. The third supporting-portion is located on the second supporting-portion, is connected to the sensing-portion, and is connected to the second supporting-portion through a second dielectric material.

This application claims the benefit of U.S. provisional application Ser. No. 63/189,752, filed May 18, 2021, the subject matter of which is incorporated herein by reference.

### BACKGROUND OF THE DISCLOSURE

### Field of the Disclosure

The disclosure relates in general to a micro-electro-mechanical system (MEMS) and the fabricating method thereof, and more particularly to a MEMS bone-conduction microphone and the fabricating method thereof.

### Description of the Related Art

Voice communication systems (VCS) and speech recognition technology typically use acoustic microphones to pick up the sound waves generated by the user's speech. Currently, a MEMS vibration sensor (used to detect the vibration of the bones and tissues in the ear canal) is provided on the basis of a traditional MEMS microphone (used to detect the weaker airborne sound of higher speech frequency) to convert the sound waves into mechanical vibrations of different frequencies. Wherein, the MEMS vibration sensor can be mounted on the inner wall of the shell of the earphone by suitable adhesive or glue.

However, this MEMS vibration sensor has problems of occupying a large space, which is not conducive to product miniaturization, and poor sensitivity.

### SUMMARY OF THE DISCLOSURE

Therefore, there is a need to provide a MEMS bone-conduction microphone and the fabricating method thereof to overcome the drawbacks of the prior art.

One embodiment of the present disclosure is to provide a MEMS vibration sensor, wherein the MEM vibration sensor includes a substrate and a sensing-device. The substrate includes a first supporting-portion and a cavity. The sensing-device includes a first sensing-unit, a second sensing-unit, a first metal pad and a second metal pad. The first sensing-unit includes a second supporting-portion and a vibrating-portion. The second supporting-portion is disposed on the first supporting-portion and is connected to the first supporting-portion via a first dielectric material. The vibrating-portion is disposed on the cavity, and is connected to the second supporting-portion via an elastic connecting-portion. The second sensing-unit is disposed on the first sensing-unit and includes a sensing-portion and a third supporting-portion. The sensing-portion is disposed on the vibrating-portion; and there is a gap between the sensing-portion and the vibrating-portion. The third supporting-portion is disposed on the second supporting-portion, is connected to the sensing-portion, and is connected to the second supporting-portion through a second dielectric material. The first metal pad is formed above the third supporting-portion and is electrically coupled with the first sensing-unit. The second metal pad is formed above the third supporting-portion and is electrically coupled with the second sensing-unit.

Another embodiment of the present disclosure is to provide a fabricating method of a MEMS vibration sensor, wherein the method includes steps as follows: A device substrate including a base layer, a first dielectric layer, and a first device material layer is provided. A first patterning process is performed to pattern the first device material layer and form a plurality of through holes therein, so as to expose a portion of the first dielectric layer and to define a vibrating-portion. A second dielectric layer is provided on the first device material layer. A second patterning process is performed to pattern the second dielectric layer, so as to expose a portion of the first device material layer. A first protection layer is formed on the exposed portions of the second dielectric layer and the first device material layer. A third patterning process is performed to pattern the first protection layer, so as to expose a portion of the first device material layer. A second device material layer is formed on the exposed portions of the first protection layer and the first device material layer. A fourth patterning process is performed to pattern the second device material layer, so as to expose a portion of the first protection layer and to define a sensing-portion corresponding to the vibrating-portion. A first metal pad and a second metal pad are formed on the second device material layer, wherein the first metal pad is electrically coupled with the patterned first device material layer, and the second metal pad is connected with the patterned second device material layer. The second element material layer is electrically coupled. A releasing process is performed to remove a portion of the base layer for forming a cavity corresponding to the vibrating-portion, and to remove a portion of the first dielectric layer and a portion of the second dielectric layer for forming a gap between the vibrating-portion and the sensing-portion.

Yet another embodiment of the present disclosure is to provide a fabricating method of a MEMS vibration sensor, wherein the method includes steps as follows: A device substrate including a base layer, a first dielectric layer, and a first device material layer is provided. A first patterning process is performed to pattern the first device material layer and form a plurality of through holes therein, so as to expose a portion of the first dielectric layer and to define a vibrating-portion. A second dielectric layer is provided on the first device material layer. A second patterning process is performed to pattern the second dielectric layer, so as to expose a portion of the first device material layer. A second device material layer is formed on the second dielectric layer. A fourth patterning process is performed to pattern the second element material layer, so as to define a sensing-portion corresponding to the vibrating-portion. A first metal pad and a second metal pad are formed on the second device material layer, wherein the first metal pad is electrically coupled with the patterned first device material layer, and the second metal pad is connected with the patterned second device material layer. The second element material layer is electrically coupled. A releasing process is performed to remove a portion of the base layer for forming a cavity corresponding to the vibrating-portion, and to remove a portion of the first dielectric layer and a portion of the second dielectric layer for forming a gap between the vibrating-portion and the sensing-portion.

The above and other aspects of the disclosure will become better understood with regard to the following detailed description of the preferred but non-limiting embodiment(s). The following description is made with reference to the accompanying drawings:

### BRIEF DESCRIPTION OF THE DRAWINGS

FIG. 1A is a top view illustrating the structure of a MEMS vibration sensor according to one embodiment of the present disclosure;

FIG. 1B is a bottom view of the structure of the MEMS vibration sensor as depicted in FIG. 1A;

FIG. 1C is a cross-sectional view illustrating the structure of the MEMS vibration sensor taking along the cutting line 1A-1A′ as depicted in FIG. 1A;

FIGS. 2A to 2M are a serios cross-sectional views illustrating the processing structures for fabricating the MEMS vibration sensor as depicted in FIGS. 1A to 1C;

FIG. 3 is a cross-sectional view illustrating the structure of a MEMS vibration sensor according to another embodiment of the present disclosure;

FIG. 4 is a cross-sectional view illustrating the structure of a MEMS vibration sensor according to yet another embodiment of the present disclosure;

FIG. 5 is a cross-sectional view illustrating the structure of a MEMS vibration sensor according to yet another embodiment of the present disclosure; and

FIG. 6 is a cross-sectional view illustrating a MEMS package structure including a MEMS vibration sensor according to one embodiment of the present disclosure.

### DETAILED DESCRIPTION OF THE DISCLOSURE

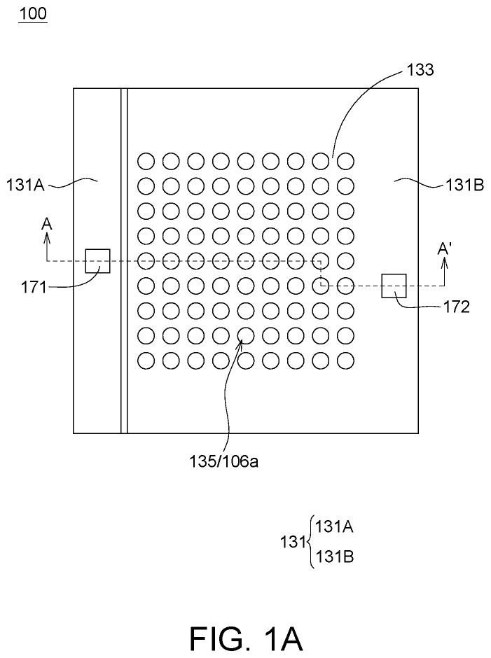

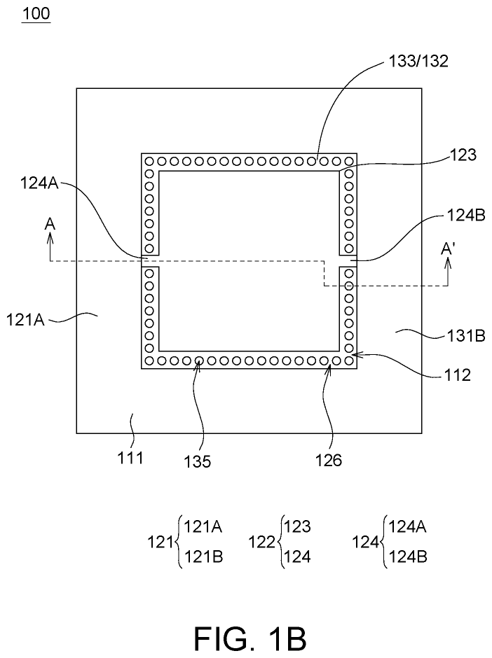

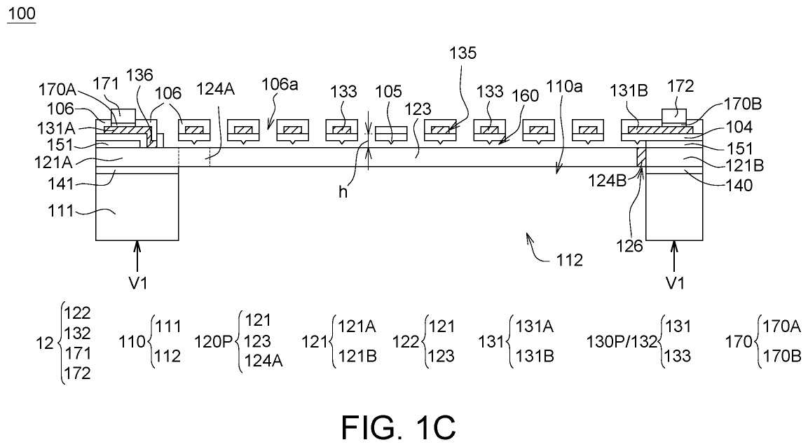

FIG. 1A is a top view illustrating the structure of a MEMS vibration sensor 100 according to one embodiment of the present disclosure. FIG. 1B is a bottom view of the structure of the MEMS vibration sensor 100 as depicted in FIG. 1A. FIG. 1C is a cross-sectional view illustrating the structure of the MEMS vibration sensor 100 taking along the cutting line 1A-1A′ as depicted in FIG. 1A.

The MEMS vibration sensor 100 can be applied in, for example, a vibration detector, a microphone, a sound-receiving apparatus, and the like. The MEMS vibration sensor 100 and the MEMS package structure applying the same can be utilized in headphones, automobiles, wheels, home appliances, industrial instruments and other items that are subjected to vibration analysis according to the received vibration (eg, audio vibration).

The MEMS vibration sensor 100 includes a base layer 110 and a sensing device 12. The base layer 110 includes a first supporting-portion 111 and a cavity 112. The sensing device 12 includes a first sensing-unit 122, a second sensing-unit 132, a first metal pad 171 and a second metal pad 172.

The first sensing-unit 122 includes a second supporting-portion 121 and a vibrating-portion 123. The second supporting-portion 121 is disposed above a first second supporting-portion 111 and is connected to the first second supporting-portion 111 via a first dielectric material 141. The vibrating-portion 123 is disposed above the cavity 112 and is connected to the second supporting-portion 121 via an elastic connecting-portion 124.

The second sensing-unit 132 is disposed above the first sensing-unit 122 and includes a sensing-portion 133 and a third supporting-portion 131. The sensing-portion 133 is disposed above the vibrating part 123; and there has a gap 160 between the sensing-portion 133 and the vibrating-portion 123. The third supporting-portion 131 is disposed above the second supporting-portion 121, is connected to the sensing-portion 133, and is connected to the second supporting-portion 121 via a second dielectric material 151.

The first metal pad 171 is disposed above the third supporting-portion 131 and is electrically coupled to the first sensing-unit 122. The second metal pad 172 is disposed on the third supporting-portion 131, is electrically isolated from the first metal pad 171, and is electrically coupled to the second sensing-unit 132.

The vibrating-portion 123 may be a cantilever, one end of which is laterally extended from the second supporting-portion 121 to above the cavity 112, and the other end is isolated from the second supporting-portion 121. The third supporting-portion 131 includes a first part 131A and a second part 131B that are electrically isolated from each other. The first metal pad 171 is formed on the first part 131A, and the second metal pad 172 is formed on the second part 131B.

By this arrangement, the vibrating-portion 123 can sense and amplify the amplitude of the external vibration source V1. The vibrating-portion 123 can be driven by the elastic connecting-portion 124 waving up and down relative to the second sensing-unit 132, which may alter the distance h of the gap 160 between the sensing-portion 133 and the vibrating-portion 123, thus causing the change in capacitance. The signal generated by the changed capacitance can be transmitted outward by the first metal pad 171 and the second metal pad 172 to a processor (not shown) for processing, calculation and/or analysis, and corresponding actions are performed accordingly.

Wherein, the vibration source V1 can be transmitted to the first sensing-unit 122 through solid or air. In the present embodiment, the vibration source V1 can be transmitted to the first sensing-unit 122 through the first supporting-portion 111 of the base layer 110, the first dielectric material 141 and the second supporting-portion 121 (called solid-conduction).

In detail, the base layer 110 may be, for example, a silicon substrate, a silicon wafer or a layer made of other suitable semiconductor materials, but the embodiments of the present disclosure are not limited thereto. The cavity 112 is a through hole formed in the base layer 110, passing through the upper surface 110a and the lower surface 110b of the base layer 110, and is defined by the vertical wall(s) of the first supporting-portion 111. In other words, the sidewall(s) of the cavity 112 is the vertical wall(s) of the first supporting-portion 111.

In some embodiments of the present disclosure, the second supporting-portion 121, the vibrating-portion 123 and the elastic connecting-portion 124 are made of a conductive material. The conductive material described herein may, for example, includes a semiconductor material (e.g., polysilicon, silicon carbide (SiC), single crystal, or other semiconductor materials with conductive properties caused by ion implantation or doping), metal (e.g., copper), alloy material, or other suitable conductive material, or any of the arbitrary combinations thereof. For example, in some embodiments of the present disclosure, the second supporting-portion 121, the vibrating-portion 123 and the elastic connecting-portion 124 are included in a patterned first device material layer 120P; and the patterned first device material layer 120P may include polysilicon.

In some embodiments of the present specification, the vibrating-portion 123 is disposed in the area where the patterned first device material layer 120P overlaps the cavity 112, and is connected to the second supporting-portion 121 via the elastic connecting-portion 124. Specifically, the vibrating-portion 123 is a square area disposed in the center of the area where the patterned first device material layer 120P overlaps the cavity 112. The area where the patterned first device material layer 120P overlaps the cavity 112 also includes a plurality of through holes (For example, two U-shaped through holes 126) used to define the elastic connecting-portion 124, so that the vibrating-portion 123 is connected to the second supporting-portion 121 via the elastic connecting-portion 124.

In the present embodiment (as shown in FIG. 1A), the elastic connecting-portion 124 may include two elongated beam structures 124A and 124B (also referred to as the first sub-elastic connecting-portion 124A and the second sub-elastic connecting-portion) respectively disposed on the left side and right side of the vibrating-portion 123. One ends of the elongated beam structures 124A and 124B respectively extend from the first portion 121A and the second portion 121B of the second supporting-portion 121 (disposed at the left side and right side) laterally to the center of the cavity 112. The other ends of the elongated beam structures 124A and 124B are respectively connected to the vibrating-portion 123 disposed above the cavity 112.

However, the geometric structure of the elastic connecting-portion 124 is not limited thereto. In addition, the geometric structure of the elastic connecting-portion 124 can be adjusted/changed to make the first sensing-unit 122 having proper rigidity (stiffness) to obtain the desired vibration detection characteristics, such as, the sensitivity for different vibration frequencies and/or increased detection bandwidth.

Specifically, for example, in another embodiment of the present disclosure (not shown), the elastic connecting-portion 124 may only include a single elongated beam structures 124A connecting the second part 131B of the third supporting-portion 131 and the vibrating-portion 123, but not include the elongated beam structure 124B connecting the first part 131A of the third supporting-portion 131 and the vibrating-portion 123. In this way, the rigidity of the first sensing-unit 122 can be weakened for releasing the stress, so that the vibration can be more easily transmitted to the vibrating-portion 123.

In another embodiment of the present disclosure, the elastic connecting-portion 124 may include four elongated beam structures (not shown) respectively defined by four through holes (not shown) on the four sides of the vibrating-portion 123 in the area where the patterned first device material layer 120P overlaps the cavity 112. In this way, the rigidity of first sensing-unit 122 can be strengthened to prevent the elastic connecting-portion 124 and the vibrating-portion 123 from abnormal warping after subjected to vibration.

In addition, the elastic connecting-portion 124 may further include at least one rigidity adjustment structure, such as a protruding structure (such as at least one rib (not shown) and/or protruding bump (not shown), etc.) for strengthening the rigidity, and/or corrugated or hollow structures (such as blind holes and/or through holes (not shown), etc.) that can weaken rigidity. In the embodiments of the present disclosure the shape, number and/or size of the protruding structure and/or the hollow structure are not limited.

The second sensing-unit 132 includes the third supporting-portion 131, and the sensing-portion 133 connected to the third supporting-portion 131. In some embodiments of the present disclosure, the third supporting-portion 131 and the sensing-portion 133 of the second sensing-unit 132 are included in a patterned second device material layer 130P. Wherein, the second device material layer 130P is also composed of a conductive material (including metal materials and/or semiconductor materials).

As shown in FIG. 1A, the sensing-portion 133 is disposed in the area where the patterned second device material layer 130P overlaps the cavity 112, and includes a plurality of through holes 135. The first part 131A and the second part 131B of the third supporting-portion 131 that are electrically isolated from each other are respectively disposed at the peripheral left side and right side of the sensing-portion 133. Wherein the first part 131A is electrically isolated from the sensing-portion 133; and the second part 131B is electrically connected to the sensing-portion 133.

At least one dimple/bump 105 may be further provided between the sensing-portion 133 of the second sensing-unit 132 and the vibrating-portion 123 of the first sensing-unit 122 to prevent the sensing-portion 133 of the second sensing-unit 132 from being contact and/or sticking to the vibrating-portion 123 of the first sensing-unit 122. A sensing unit 122 contacts and sticks. In some embodiments of the present disclosure, the material constituting the dimple/bump 105 may be a dielectric material, such as oxide or silicon nitride. In other embodiments of the present disclosure, the material constituting the dimple/bump 105 may be the same as the material constituting the patterned second device material layer 130P.

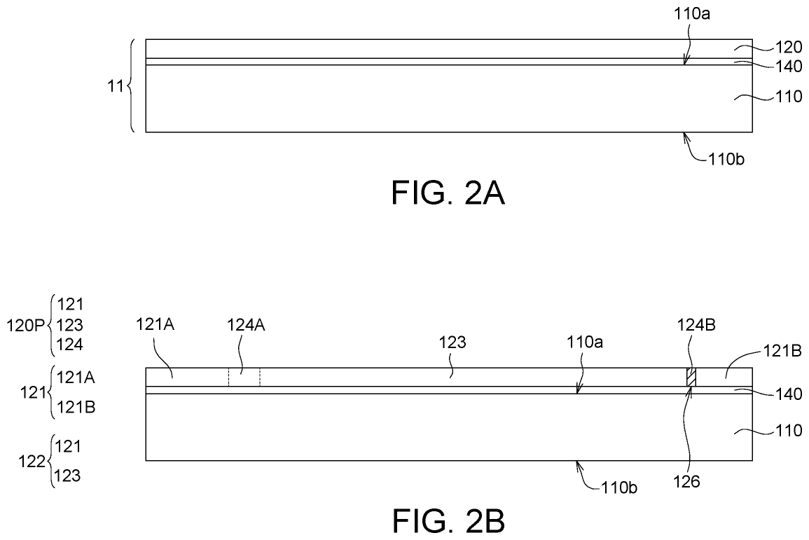

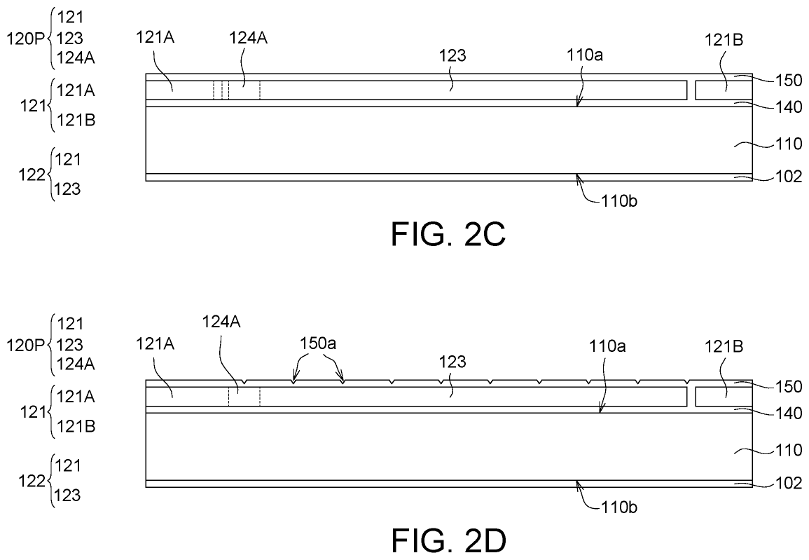

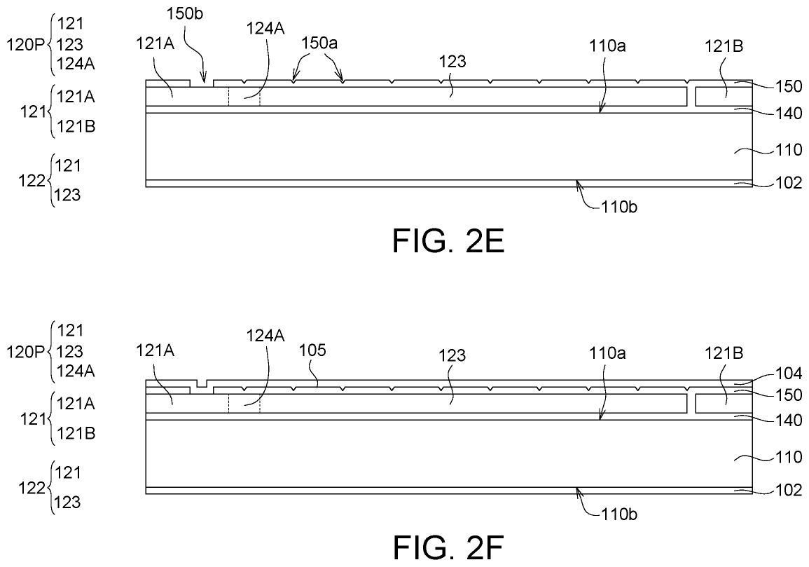

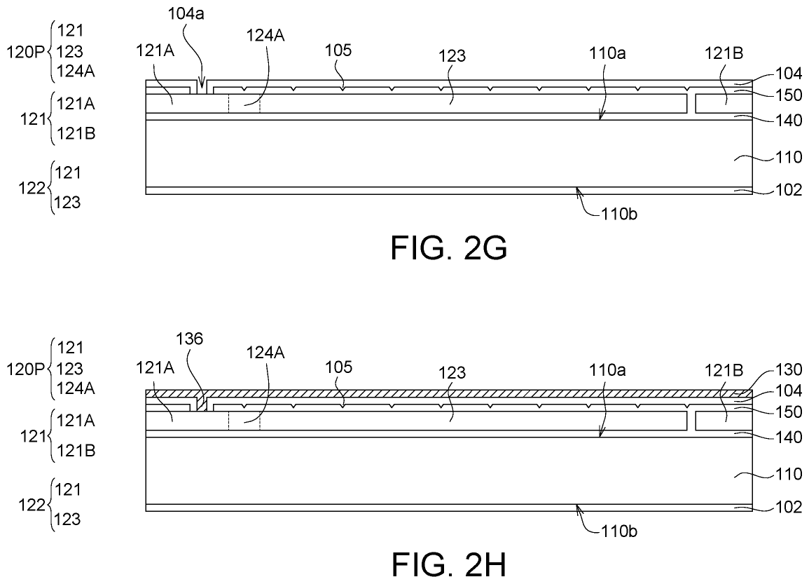

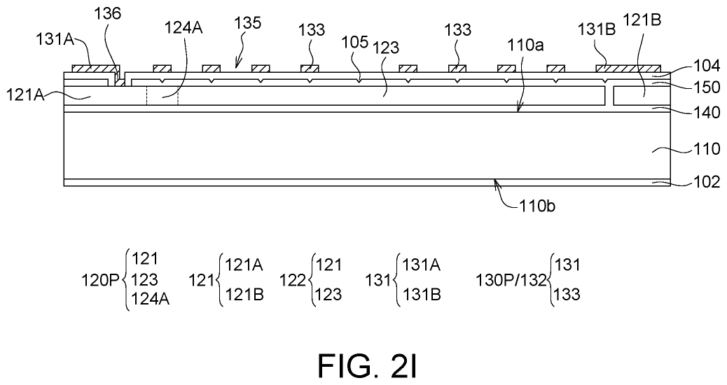

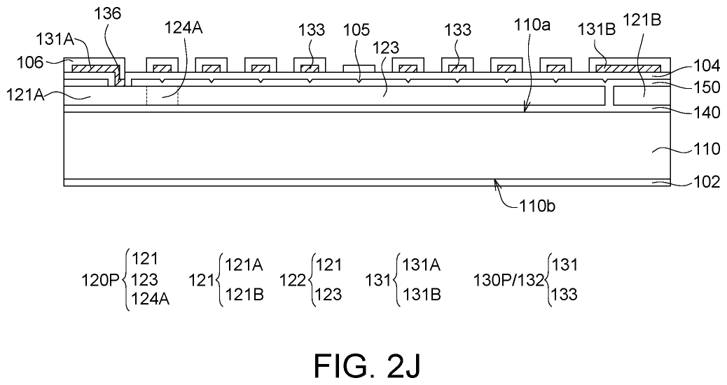

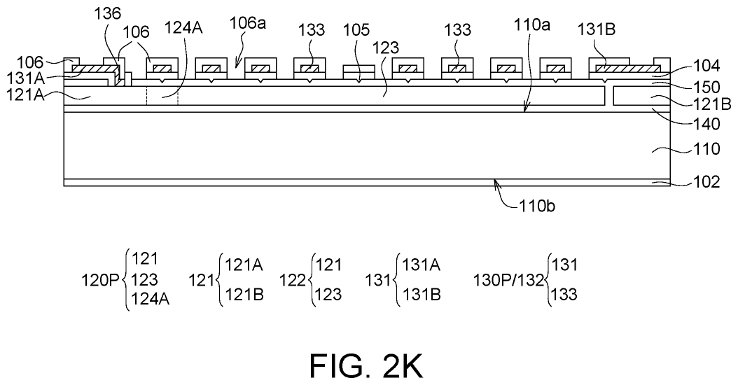

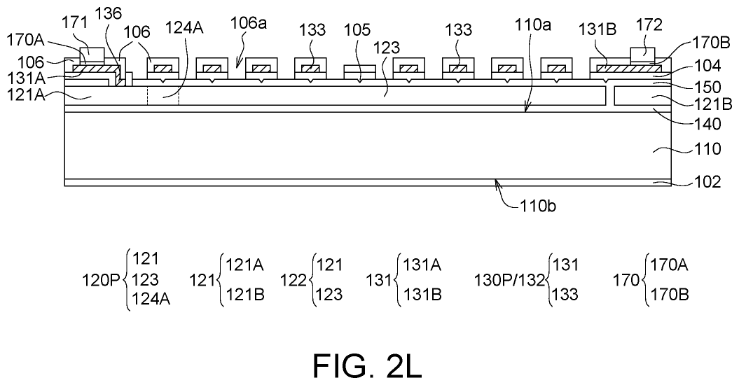

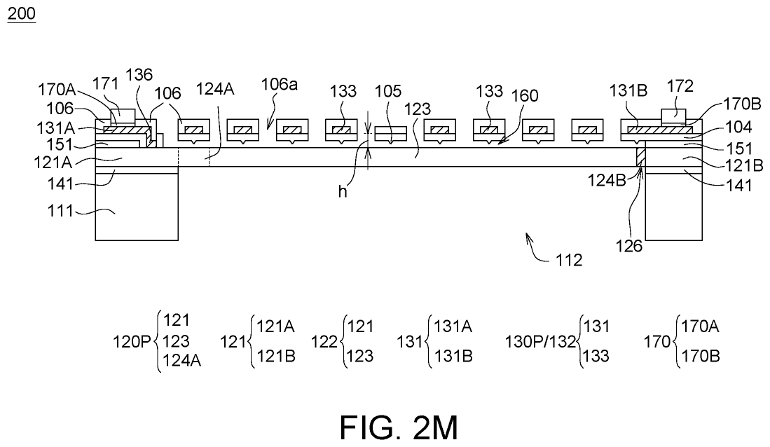

FIGS. 2A to 2M are a serios cross-sectional views illustrating the processing structures for fabricating the MEMS vibration sensor 100 as depicted in FIGS. 1A to 1C.

As shown in FIG. 2A, a device substrate 11 is provided, wherein the device substrate 11 includes a dielectric layer 140 and a first device material layer 120 sequentially stacked on an upper surface 110a of a base layer 110. In one embodiment of the present disclosure, the base layer 110 may be, for example, a silicon substrate. However, the embodiment of the present disclosure is not limited thereto, and the base layer 110 may include other suitable semiconductor materials.

The material constituting the dielectric layer 140 may include silicon oxide, silicon nitride and/or other suitable dielectric materials. The step of forming the dielectric layer 140 may include a deposition process (e.g., a plasma enhanced oxide (PEOX) deposition process) or a thermal oxide deposition process. Material constituting the first device material layer 120 may include semiconductor material (e.g., poly-silicon), metal (e.g., copper), alloy material, or other suitable conductive material or any of the arbitrary combinations thereof. In another embodiment of the present specification, the step of providing the device substrate 11 may include providing a silicon-on-insulator (SOI) substrate.

As shown in FIG. 2B, a first patterning step is performed to pattern the first device material layer 120 to form a plurality of through holes (e.g., the plurality of U-shaped through holes 126), and to expose a portion of the dielectric layer 140. In the present embodiment, a photolithography etching process, including steps of coating (photoresist), exposure, development and/or etching, is performed to pattern the first device material layer 120, so as to form the plurality of U-shaped through holes 126 in the first device material layer 120 to expose portions of the dielectric layer 140. Thereby forming a patterned first device material layer 120P having the second supporting-portion 121, the vibrating-portion 123 and the elastic connecting-portion 124.

As shown in FIG. 2C, a dielectric layer 150 is provided over the first device material layer 120 (i.e., the patterned first device material layer 120P). In the present embodiment, the method for providing the dielectric layer 150 includes the following steps (but not limited thereto): Firstly, a thermal oxidation process is performed on the base layer 110 and the patterned first device material layer 120P (or performing at least one electrical material deposition process) to form the dielectric layers 102 and 150 on the lower surface 110b of the base layer 110 and the upper surface of the patterned first device material layer 120P, respectively, and to fill the U-shaped through holes 126 with the dielectric material. Then, the dielectric layer 150 is planarized by a chemical mechanical polishing (CMP) process. The material constituting the dielectric layers 102 and 150 may preferably include silicon oxide.

Subsequently, the dielectric layer 150 is patterned to expose a portion of the first device material layer 120 (i.e., the patterned first device material layer 120P). In some embodiments of the present disclosure, the process for patterning the dielectric layer 150 includes steps as follows: Firstly, a lithography etching process is performed to remove a portion of the dielectric material layer 150 corresponding to the first sensing-unit 122 to form a plurality of recesses 150a (as shown in FIG. 2D). Another lithography etching process is then performed to remove another portion of the dielectric layer 150 corresponding to the second supporting-portion 121, so as to form a plurality of through holes 150b exposing parts of the second supporting-portion 121 and that is included in the first device material layer 120 (i.e., the patterned first device material layer 120P) (as shown in FIG. 2E).

As shown in FIG. 2F, the first protection layer 104 is formed on the exposed portions of the dielectric layer 150 and the first device material layer 120 (i.e., the patterned first element layer 120P). In some embodiments of the present disclosure, a deposition process may be performed to deposit a dielectric material over the dielectric layer 150 and fill the recesses 150a and the through holes 150b to form the first protection layer 104. In one embodiment, the material constituting the first protection layer 104 is different from the material constituting the dielectric layer 150. In the present embodiment, the material constituting the first protection layer 104 may include silicon nitride or silicon oxynitride (but not limited thereto). The portions of the first protection layer 104 filled in the recesses 150a may serve as the plurality of dimples/bumps 105 after subjected to the steps subsequently described.

As shown in FIG. 2G, a third patterning step is performed to pattern the first protection layer 104 and expose a portion of the first device material layer 120 (i.e., the patterned first element layer 120P). In some embodiments of the present disclosure, a portion of the first protection layer 104 is removed by a lithography etching process to form the through hole 104a and expose a portion of the second supporting-portion 121 included in the first device material layer 120 (i.e., the patterned first element layer 120P).

As shown in FIG. 2H, the second device material layer 130 is formed on the first protection layer 104 and the exposed portion of the first device material layer 120 (i.e., the patterned first element layer 120P). In some embodiments of the present disclosure, the forming of the second device material layer 130 includes steps as follows: A deposition process is performed to deposit semiconductor material (e.g., poly-silicon, silicon carbide, monocrystalline silicon, or semiconductor materials with conductive properties provided through ion implantation or doping processes), metal (e.g., copper), alloy, or other suitable conductive material) on the first protection layer 104 and fill the through holes 104a, so as to form conductive plugs 136 electrically connecting the second device material layer 130 and the second supporting-portion 121 of the first patterned device material layer 120P.

As shown in FIG. 2I, a fourth patterning step is performed to pattern the second device material layer 130 and expose a portion of the first protection layer 104. In some embodiments of the present disclosure, a lithography etching process is performed to remove a portion of the second device material layer 130 to form a plurality of through holes 135 and expose a portion of the first protection layer 104; thereby the patterned second device material layer 130P including the third supporting-portion 131 and the sensing-portion 133 can be formed. Wherein the plurality of through holes 135 are formed in the sensing-portion 133; the third supporting-portion 131 can be further divided into a first part 131A and a second part 131B isolated from each other; and the first part 131A is electrically connected to the second supporting-portion 121 of the patterned first device material layer 120P through the conductive plug 136.

As shown in FIG. 2J, a second protection layer 106 is formed over the second device material layer 130 (i.e., the patterned second device material layer 130P). In some embodiments of the present disclosure, a deposition process can be performed over the second device material layer 130 for depositing dielectric material and filling the through holes 135, so as to form the second protection layer 106. The material constituting the second protection layer 106 may be the same as or different from the material constituting the first protection layer 104. For example, in this embodiment, the material constituting the second protection layer 106 may be silicon nitride or silicon oxynitride (but not limited thereto).

As shown in FIG. 2K, a fifth patterning step is performed to pattern the second protection layer 106, so as to expose a part of the second device material layer 130 (i.e., the patterned second device material layer 130P). In some embodiments of the present disclosure, a lithography etching process is performed to remove a portion of the second protection layer 106, so as to form a plurality of through holes 106a exposing a portion of the third supporting-portion 131 (e.g., the first part 131A and the second part 131B) of the second device material layer 130 (i.e., the patterned second device material layer 130P) and form a plurality of through holes 106b exposing a portion of the dielectric material layer 150.

As shown in FIG. 2L, the first metal pad 171 and the second metal pad 172 are formed on the second device material layer 130 (i.e., the patterned second device material layer 130P), wherein the first metal pad 171 is electrically coupled to the first device material layer 120 (i.e., the patterned first device material layer 120P), and the second metal pad 172 is electrically coupled to the second device material layer 130 (i.e., the patterned second device material layer 130P).

In some embodiments of the present disclosure, the forming of the first metal pads 171 and the second metal pads 172 includes steps as follows: Firstly, an electrode layer 170 is formed over the second protection layer 106 by a metal deposition process to fill the through holes 106a. The electrode layer 170 is then patterned to remove a portion thereof, so as to at least divide the electrode layer 170 into a first partial electrode layer 170A and a second partial electrode layer 170B which are electrically isolated from each other. The first partial electrode layer 170A is electrically coupled to the first part 131A of the second device material layer 130 (i.e., the patterned second device material layer 130P); the second partial electrode layer 170B is electrically coupled to the second part 131B of the second device material layer 130 (i.e., the patterned second device material layer 130P). Subsequently, a serious of process, such as a metal deposition, a lithography etching process and/or a photoresist-lift-off process, etc., may be performed to form the first metal pad 171 and the second metal pad 172 that are electrically isolated from each other and are respectively disposed on the first partial electrode layer 170A and the second partial electrode layer 170B.

As shown in FIG. 2M, a releasing process is performed to remove a portion of the base layer 110 for forming the cavity 112, to remove a portion of the dielectric layer 140 and a portion of the dielectric layer 150 for forming the gap 160 between the first device material layer (i.e., the patterned first device material layer 120P) and the second device material layer 130 (i.e., the patterned second device material layer 130P).

In some embodiments of the present disclosure, at least one lithography etching process is firstly performed to remove a portion of the base layer 110, so as to form the cavity 112 penetrating the upper surface 110a of the base layer 110 and the lower surface 110b of the base layer 110. Then at least one wet cleaning (etching) process is performed to remove the portion of the dielectric layer 140 disposed in the through holes 126 via the cavity 112 and the through hole 106a, and to remove the portion of the dielectric material layer 150 disposed between the sensing-portion 133 and the first sensing-unit 122. In the present embodiment, the remaining portion of the base layer 110 used to define the cavity 112 can serve as the first supporting-portion 111 of the MEMS vibration sensor 100. The remaining portion of the dielectric layer 140 disposed above the first supporting-portion 111 may serve as the first dielectric material 141 connected to the first supporting-portion 111.

After a series of down-stream processes are performed, the preparation of the MEMS vibration sensor 100 can be completed. Since the remaining manufacturing steps of the down-stream processes are the same as or similar to the corresponding manufacturing steps of the conventional MEMS vibration sensor, thus they will not be redundantly repeated here.

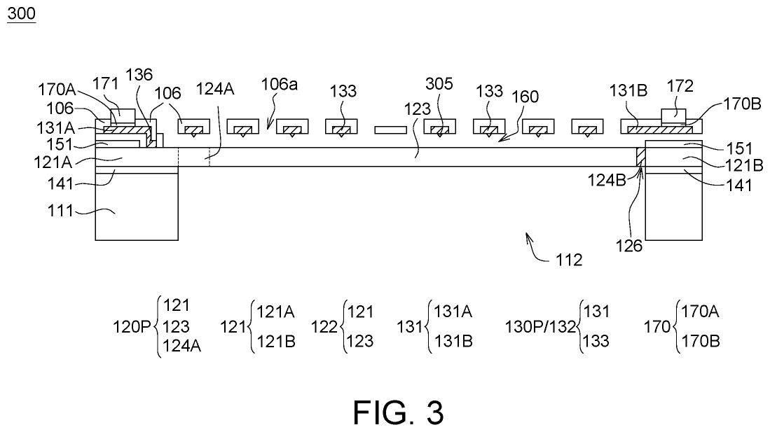

FIG. 3 is a cross-sectional view illustrating the structure of a MEMS vibration sensor 300 according to another embodiment of the present disclosure. In the present embodiment, the processing structures for fabricating the MEMS vibration sensor 300 is substantially similar to that for fabricating the MEMS vibration sensor 100 as depicted in FIGS. 1A to 1C, the difference there between is that the process steps for forming the MEMS vibration sensor 300 omits the steps for forming the first protection layer 104 over the dielectric layer 150 and the first device material layer 120 (as shown in FIG. 2F).

Therefore, there are no first protective layer 104; and when the second sensing-unit 132 is formed, the dimples/bumps 105 of the same material as the second sensing-unit 132 (the patterned second element layer 130P) can be formed between the second sensing-unit 132 and the first sensing-unit 122 of the MEMS vibration sensor 300. Since the corresponding (remaining) structure, materials and manufacturing steps of the MEMS vibration sensor 300 are the same as or similar to that of the MEMS vibration sensor 100, thus they will not be redundantly repeated here.

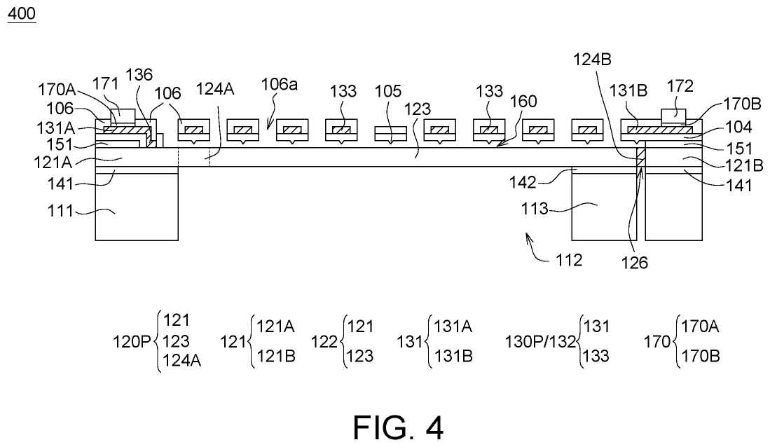

FIG. 4 is a cross-sectional view illustrating the structure of a MEMS vibration sensor 400 according to yet another embodiment of the present disclosure. In the present embodiment, the processing structures for fabricating the MEMS vibration sensor 400 is substantially similar to that for fabricating the MEMS vibration sensor 100 as depicted in FIGS. 1A to 1C, the difference there between is that the process steps for forming the MEMS vibration sensor 400 further includes a mass-block 113 disposed in the cavity 112 and connected to the vibrating-portion 123 via a fourth dielectric material 142. The mass-block 113 can shift within a limited range in the cavity 112 in conjunction with the actions of the first sensing-unit 122 to improve the sensitivity of the MEMS vibration sensor 400.

In the present embodiment, the mass-block 113 and the fourth dielectric material 142 may be the remaining portions of the base layer 110 and the dielectric layer 140, respectively, that are reserved from the release step (as shown in FIG. 2M). In other words, the mass-block 113 and the first supporting-portion 111 are made of the same material; the fourth dielectric material 142 and the first dielectric material 141 are made of the same material. Since the corresponding (remaining) structure, materials and manufacturing steps of the MEMS vibration sensor 400 are the same as or similar to that of the MEMS vibration sensor 100, thus they will not be redundantly repeated here.

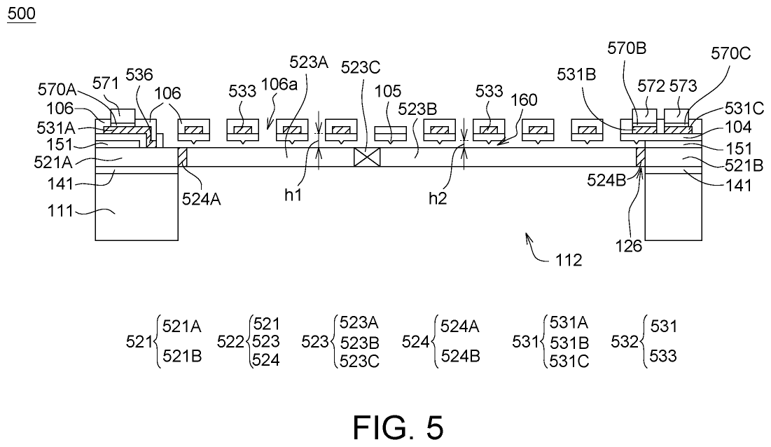

FIG. 5 is a cross-sectional view illustrating the structure of a MEMS vibration sensor 500 according to yet another embodiment of the present disclosure. In the present embodiment, the processing structures for fabricating the MEMS vibration sensor 500 is substantially similar to that for fabricating the MEMS vibration sensor 100 as depicted in FIGS. 1A to 1C, the difference there between is that the vibrating-portion 523 of the MEMS vibration sensor 500 may include a first sub-vibrating-portion 523A, a second sub-vibrating-portion 523B, and a pivot member 523C pivotally connecting the first sub-vibrating-portion 523A and the second sub-vibrating-portion 523B. And the MEMS vibration sensor 500 further includes a third metal pad 573 disposed on a third part 531C of the third supporting-portion 531.

The first metal pad 571 (together with the first partial electrode layer 570A) is disposed on the first part 531A of the third supporting-portion 531, and is electrically coupled to the first sub-vibrating-portion 523A of the first sensing-unit 522 through the conductive plug 536, the first portion 521A (on the left side of the second supporting-portion 521) and the first sub-elastic connecting-portion (i.e., the elongated beam structure 524A). The second metal pad 572 (together with the second partial electrode layer 570B) is disposed on the second part 531B of the third support portion 531, electrically isolated from the first metal pad 571 and the third metal pad 573, respectively; and electrically coupled to the sensing-portion 533 of the second sensing-unit 532 through the second part 531B. The third metal pad 573 (together with the third partial electrode layer 570C) is disposed on the third part 531C; and is electrically coupled to the second sub-vibrating-portion 523B of the first sensing-unit 522 through the conductive plug (not shown), the second supporting-portion 521B (on the right side of the second supporting-portion 521) and the second sub-elastic connecting-portion (i.e., the elongated beam structure 524B).

In the present embodiment, the first sub-vibrating-portion 523A is connected to the first portion 521A (on the left side of the second supporting-portion 521) through the first sub-elastic connecting-portion (i.e., the elongated beam structure 524A). The second sub-vibrating-portion 523B is connected to the second supporting-portion 521B (on the right side of the second supporting-portion 521) through the second sub-elastic connecting-portion (i.e., the elongated beam structure 524B). The first sub-vibrating-portion 523A is electrically connected to the first metal pad 571 that is disposed on the first part 531A through the elongated beam structure 524A, the first portion 521A (on the left side of the second supporting-portion 521), the conductive plug 536 and the first part 531A of the third supporting-portion 531. The second sub-vibrating-portion 523B is electrically connected to the third metal pad 573 that is disposed on the third part 531C through the elongated beam structure 524B, the second portion 521B (on the right side of the second supporting-portion 521), the conductive plug (not shown) and the third part 531C of the third supporting-portion 531.

The first sub-vibrating-portion 523A and the second sub-vibrating-portion 523B can sense and amplify the amplitude of the external vibration source V1. The sub-vibrating-portion 523A and the second sub-vibrating-portion 523B can be respectively driven by the first sub-elastic connecting-portion (the elongated beam structure 524A) and the second sub-elastic connecting-portion (the elongated beam structure 524B) waving up and down relative to second sensing-unit 532, which may alter the gap distance h1 between the sub-vibrating-portion 523A and the sensing-portion 533 and the gap distance h2 between the sub-vibrating-portion 523B and the sensing-portion 533, and thus causing the change in capacitance between the first sensing-unit 522 (including the sub-vibrating-portions 523A and 523B) and the second sensing-unit 532. The signal generated by the changed capacitance can be transmitted outward by the first metal pad 571 the second metal pad 572 and the third metal pad 573 to a processor (not shown) for processing, calculation and/or analysis, and corresponding actions are performed accordingly.

In some embodiments of the present disclosure, the pivot member 523C can be a semiconductor hinge embedded in the first device material layer 120 (i.e., the patterned first device material layer 120P) and formed by deposition, lithography and other processes carrying out prior to the forming of the dielectric layer 150 (as shown in FIG. 2C). In other embodiments of the present specification, the pivot member 523C may be replaced by an elastic member.

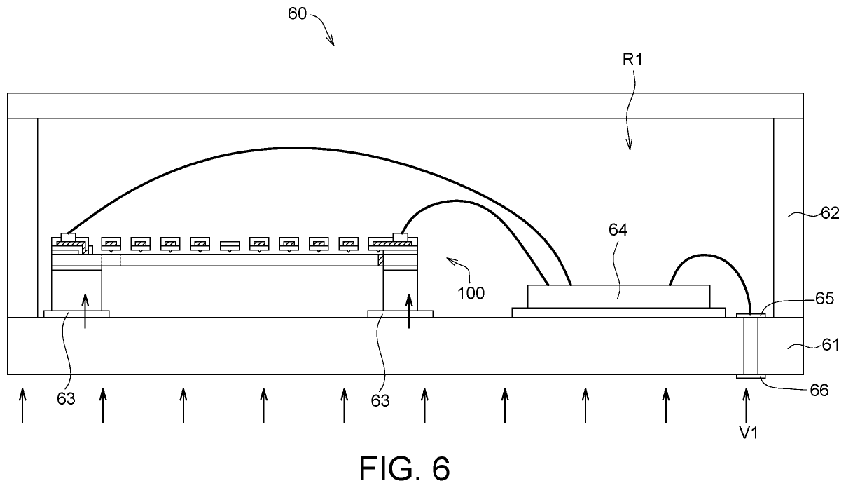

FIG. 6 is a cross-sectional view illustrating a MEMS package structure 60 including a MEMS vibration sensor 100 according to one embodiment of the present disclosure. The MEMS package structure 60 may include a MEMS vibration sensor 100, a carrier board 61, a casing 62, a load pads 63, an integrated circuit (IC) die 64, at least one first contact 65 and at least one second contact 66. The carrier board 61 and the casing 62 can define an accommodating space R1. The MEMS vibration sensor 100 can be disposed on the load pads 63 of the carrier board 61. The load pads 63 have insulating properties and/or thermal conductivity. The IC die 64 may be disposed on the carrier board 61. The MEMS vibration sensor 100 can be electrically coupled to the IC die 64 and the carrier board 13, respectively, using the connecting wires 67 by a wire bonding process. The carrier board 61 may be a part of a printed circuit board or a printed circuit board itself. In one embodiment of the present disclosure, the IC die 64 is an application specific integrated circuit (ASIC) chip. The sensing signal collected by the MEMS vibration sensor 100, after being transmitted to the IC die 64 through the connecting wire 67 for processing, can be outputted through the first contact 65 and the second contact 66.

In one embodiment of the present disclosure, the carrier board 61 can be disposed close to the direction of the signal source V1, which includes a solid conduction path, such as the ear bone and the like. In another embodiment of the present disclosure, the inner space of the MEMS package structure 60 can be filled with gas (e.g., nitrogen gas) to avoid the metal pads 171/172 and the metal wires from being oxidation, which may affect its electrical properties. In yet another embodiment, the inner space of the MEMS package structure 60 can be evacuated to reduce damping effect, energy loss or mechanical dissipation. In yet another embodiment, the MEMS vibration sensor 100 of the MEMS package structure 60 can be replaced by any one of the MEMS vibration sensors 300, 400 and 500 as discussed above.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A micro-electro-mechanical system (MEMS) vibration sensor, comprising:
a substrate, comprising a first supporting-portion and a cavity; and
a sensing-device disposed on the substrate, comprising:
a first sensing-unit, comprising:
a second supporting-portion, disposed on the first supporting-portion and connected to the first supporting-portion via a first dielectric material; and
a vibrating-portion, disposed on the cavity, and connected to the second supporting-portion via an elastic connecting-portion;
a second sensing-unit, comprising:
a sensing-portion, disposed on the vibrating-portion, wherein a gap is forming between the sensing-portion and the vibrating-portion; and
a third supporting-portion, disposed on the second supporting-portion, connected to the sensing-portion, and connected to the second supporting-portion via a second dielectric material;
a first metal pad, disposed on the third supporting-portion and electrically coupled with the first sensing-unit; and
a second metal pad, disposed on the third supporting-portion and electrically coupled with the second sensing-unit.

2. The MEMS vibration sensor according to claim 1, wherein the first sensing-unit is included in a patterned first device material layer; and the second sensing-unit is included in a patterned second device material layer.

3. The MEMS vibration sensor according to claim 2, wherein the patterned first device material layer comprises metal and a semiconductor material.

4. (canceled)

5. The MEMS vibration sensor according to claim 2, wherein the patterned second device material layer comprises metal and a semiconductor material.

6. The MEMS vibration sensor according to claim 1, wherein the second sensing-unit comprises a plurality of through holes connecting the cavity and the gap.

7. The MEMS vibration sensor according to claim 1, further comprising a mass-block disposed in the cavity, connected to the vibrating-portion via a third dielectric material, and shifts within a limited range in the cavity in conjunction with actions of the first sensing-unit.

8. The MEMS vibration sensor according to claim 7, wherein the mass-block and the first supporting-portion are made of the same material; and the third dielectric material and the first dielectric material are made of the same material.

9. The MEMS vibration sensor according to claim 1, wherein third supporting-portion 131 includes a first part and a second part that are electrically isolated from each other; the first metal pad is disposed on the first part; and the second metal pad is disposed on the second part.

10. The MEMS vibration sensor according to claim 1, wherein the second dielectric material and the first dielectric material are made of the same material.

11. The MEMS vibration sensor according to claim 1, further comprising a plurality of dimples/bumps disposed between the second sensing-unit and the first sensing-unit.

12. The MEMS vibration sensor according to claim 1, further comprising a protection layer formed on a first surface of the second sensing-unit facing the first sensing-unit or on a second surface of the second sensing-unit away from the first sensing-unit.

13. The MEMS vibration sensor according to claim 1, wherein the elastic connecting-portion comprises an elongated beam structure; one end of the elongated beam structure extends from the second supporting-portion laterally to above of the cavity; and the other end of the elongated beam structure is connected to the vibrating-portion.

14. The MEMS vibration sensor according to claim 1, wherein the first sensing-unit further comprises a second elastic connecting-portion connecting second supporting-portion and the vibrating-portion.

15. The MEMS vibration sensor according to claim 1, wherein the elastic connecting-portion comprises a first sub-elastic connecting-portion and a second sub-elastic connecting-portion; and the vibrating-portion comprises:
a first sub-vibrating-portion, electrically connected to the first metal pad, and connected to the second supporting-portion through the first sub-elastic connecting-portion;
a second sub-vibrating-portion, electrically connected to the second metal pad, connected to the second supporting-portion through the second sub-elastic connecting-portion, and electrically isolated from the first sub-vibrating-portion; and
a pivot member, pivotally connecting the first sub-vibrating-portion and the second sub-vibrating-portion

16. A method for fabricating a MEMS vibration sensor, comprising:
providing a device substrate comprising a base layer, a first dielectric layer, and a first device material layer:
performing a first patterning process to pattern the first device material layer and form a plurality of through holes therein, so as to expose a portion of the first dielectric layer and to define a vibrating-portion;
forming a second dielectric layer over the first device material layer;
performing a second patterning process to pattern the second dielectric layer, so as to expose a portion of the first device material layer;
forming a first protection layer on the second dielectric layer and the first device material layer;
performing a third patterning process to pattern the first protection layer, so as to expose a portion of the first device material layer;
forming a second device material layer on the first protection layer and the first device material layer;
performing a fourth patterning process to pattern the second device material layer, so as to expose a portion of the first protection layer and to define a sensing-portion corresponding to the vibrating-portion;
forming a first metal pad and a second metal pad on the second device material layer, wherein the first metal pad is electrically coupled to the patterned first device material layer, and the second metal pad is electrically coupled to the patterned second device material layer; and
performing a releasing process to remove a portion of the base layer for forming a cavity corresponding to the vibrating-portion, and to remove a portion of the first dielectric layer and a portion of the second dielectric layer for forming a gap between the first sensing-unit and the second sensing-unit.

17. The method according to claim 16, prior to forming the first protection layer, further comprising:
patterning the second dielectric layer to form a plurality of recesses on an upper surface of the second dielectric layer; and
forming a plurality of dimples/bumps, by making portions of the first protection layer filling in the plurality of recesses when forming the first protection layer.

18. The method according to claim 16, prior to forming the first metal pad and the second metal pad, further comprising:
forming a second protection layer on the second device material layer; and
performing a fifth patterning step to pattern the second protection layer and expose a portion of the second device material layer.

19. A method for fabricating a MEMS vibration sensor, comprising:
providing a device substrate comprising a base layer, a first dielectric layer, and a first device material layer:
performing a first patterning process to pattern the first device material layer and form a plurality of through holes therein, so as to expose a portion of the first dielectric layer and to define a vibrating-portion;
forming a second dielectric layer over the first device material layer;
performing a second patterning process to pattern the second dielectric layer, so as to expose a portion of the first device material layer;
forming a second device material layer on the second dielectric layer;
performing a fourth patterning process to pattern the second device material layer, so as to define a sensing-portion corresponding to the vibrating-portion;
forming a first metal pad and a second metal pad on the second device material layer, wherein the first metal pad is electrically coupled to the patterned first device material layer, and the second metal pad is electrically coupled to the patterned second device material layer; and
performing a releasing process to remove a portion of the base layer for forming a cavity corresponding to the vibrating-portion, and to remove a portion of the first dielectric layer and a portion of the second dielectric layer for forming a gap between the first sensing-unit and the second sensing-unit.

20. The method according to claim 19, prior to forming the second device material layer, further comprising:
patterning the second dielectric layer to form a plurality of recesses on an upper surface of the second dielectric layer; and
forming a plurality of dimples/bumps, by making portions of the second device material layer filling in the plurality of recesses when forming the second device material layer.

21. The method according to claim 19, prior to forming the first metal pad and the second metal pad, further comprising:
forming a second protection layer on the second device material layer; and
performing a fifth patterning step to pattern the second protection layer and expose a portion of the second device material layer.
